(19) United States
(12) Patent Application Publication
(10) Pub. No.: US 2024/0288686 A1
(43) Pub. Date: Aug. 29, 2024

(54) PHOTOLITHOGRAPHY MASK GENERATION FOR METALENS

(71) Applicant: Synopsys, Inc., Sunnyvale, CA (US)

(72) Inventors: Bernd Kuechler, Radeberg (DE); Rainer Zimmermann, Sauerlach (DE); Maryvonne Chalony, Puget sur Argens (FR); Ulrich Karl Klostermann, München (DE); Remco Stoffer, Enschede (NL); Lawrence S. Melvin, III, Hillsboro, OR (US)

(21) Appl. No.: 18/424,984

(22) Filed: Jan. 29, 2024

Related U.S. Application Data
(60) Provisional application No. 63/487,360, filed on Feb. 28, 2023.

(51) Int. Cl. G02B 27/00; G02B 1/00

(52) U.S. Cl. CPC G02B 27/0012; G02B 1/002

(57) ABSTRACT

In an example, a target design of a metalens is obtained. The target design includes target design meta-atoms. A mask design is generated, by one or more processors, based on area deviations of to-be-fabricated meta-atoms of the metalens relative to the target design meta-atoms. The mask design may be generated using a rule-based correction, such as using a look-up table (LUT), in some examples, and may be generated using a model-based correction in some examples.

### RELATED APPLICATION

This application claims priority to and the benefit of U.S. Provisional Patent Application Ser. No. 63/487,360, filed on Feb. 28, 2023, which is incorporated herein by reference in its entirety.

### TECHNICAL FIELD

The present disclosure relates to generating a photolithography mask for fabricating a metalens.

### BACKGROUND

A metalens is generally a flat lens that manipulates a phase, amplitude, and/or polarization of light to focus light. A metalens may manipulate the phase, amplitude, and/or polarization of light, rather than implement refraction, to focus light. Metalenses use subresolution features to manipulate light phase, amplitude, and/or polarization and lens focus. Various structures within the metalens may be implemented to manipulate the phase, amplitude, and/or polarization as desired. A metalens may have applications in virtual reality, augmented reality, and others.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a method of fabricating a metalens according to some examples.

FIG. 2 is an environment in which a metalens is fabricated.

FIGS. 3A and 3B are a perspective view and layout view, respectively, of a target design meta-atom according to some examples.

FIGS. 4A and 4B are a perspective view and layout view, respectively, of a fabricated meta-atom according to some examples.

FIG. 5 is a first method for generating a mask design in FIG. 1 according to some examples.

FIG. 6 is a second method for generating a mask design in FIG. 1 according to some examples.

FIG. 7 is an example illustrating some operations of the second method of FIG. 6.

FIG. 8 depicts a diagram of an example computer system in which example methodologies of the present disclosure may operate.

### DETAILED DESCRIPTION

Aspects of the present disclosure relate to generating a photolithography mask for fabricating a metalens. According to some examples, an area of a to-be-fabricated subwavelength nano-structure within a metalens is considered when generating a photolithography mask to fabricate the metalens. A subwavelength nano-structure, as fabricated, generally is a structure that manipulates a phase, amplitude, and/or polarization of light that passes through the respective subwavelength nano-structure of the metalens. Hereinafter, a subwavelength nano-structure may also be referred to as a meta-atom. A metalens may be fabricated using photolithography and etching techniques that may be common to integrated circuit fabrication. Some examples described herein relate to generation of a photolithography mask used in a photolithography process for fabricating the metalens.

A target design of a metalens may be created with regard to a desired optical function of the metalens. However, variation in fabrication may result in the fabricated metalens varying from the target design. For example, a photolithography process used to fabricate the metalens may be frequency band limited by a projection optics lens of the photolithography process. The band limited aspect of the photolithography process may result in, e.g., higher frequency light being filtered out of the exposure pattern when patterning a photoresist. Without the higher frequency light, corner rounding may occur in the photoresist pattern, which is transferred to the metalens through etching. The corner rounding that is transferred to the metalens may be a deviation from the target design.

Deviation of a fabricated metalens from a target design may result in a loss of optical efficiency of the metalens. Different types of deviations from the target design may affect optical efficiency. One type of deviation from the target design that affects optical deviation is area deviation of fabricated meta-atoms within the metalens from target design meta-atoms of a target design. A high relation between loss of efficiency and area deviation has been observed.

Accordingly, technical advantages of the present disclosure include, but are not limited to, reducing optical efficiency loss of a fabricated metalens relative to a target design by considering area deviation. To address the technical problem of loss of optical efficiency of a fabricated metalens relative to a target design, some examples described herein consider area deviation of to-be-fabricated meta-atoms of a metalens when generating a photolithography mask that will be used to fabricate the meta-atoms. Various examples reduce area deviation of the fabricated meta-atom from the target design, and hence, may achieve a technical solution or advantage of reducing optical efficiency loss of a fabricated metalens relative to a target design. Other advantages or benefits may be achieved in various examples.

According to some examples, a metalens may be or include a transmissive material layer with fabricated meta-atoms thereon. For example, the transmissive material, during fabrication, may be a layer of silicon dioxide on a handle or support wafer (e.g., a silicon wafer) or may be a glass wafer (e.g., quartz, silicon dioxide, or another type of glass). An example fabricated meta-atom may include silicon nitride (e.g., Si₃N₄), which may have any shape or pattern. Various examples described below illustrate a meta-atom as having a generally rectangular area for simplicity and so as to not obscure various aspects of examples. However, any shape, whether regular, irregular, polygonal, freeform, etc., may be implemented for a meta-atom.

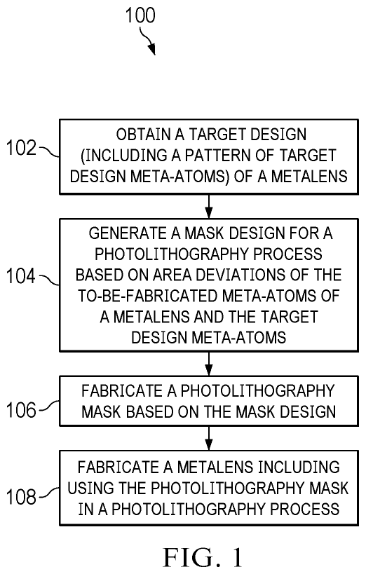

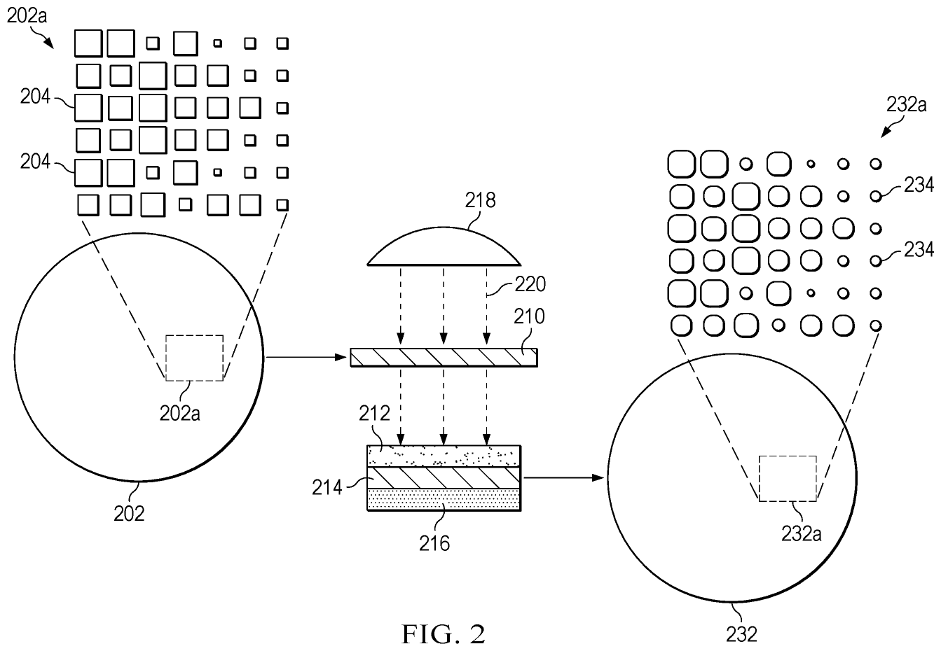

FIG. 1 is a method 100 of fabricating a metalens according to some examples. The method 100 of FIG. 1 is described with reference to the generalized environment of FIG. 2 for context.

At block 102, a target design 202 (that includes a pattern of target design meta-atoms 204) of a metalens is obtained. The target design 202 may be a design, without consideration of fabrication variation, of a metalens to achieve a desired optical function. The target design 202 may include desired shapes and pattern of target design meta-atoms 204. The inset 202a of the target design 202 in FIG. 2 shows a portion of the target design 202, which includes a pattern of target design meta-atoms 204. The areal pattern of the target design meta-atoms 204 may vary throughout a layout of the design. The pattern of target design meta-atoms 204 of FIG. 2 may be for an achromatic metalens (as illustrated) or another type of metalens, for example.

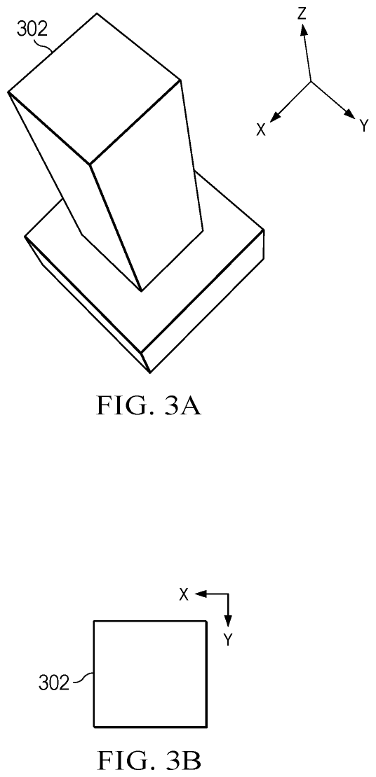

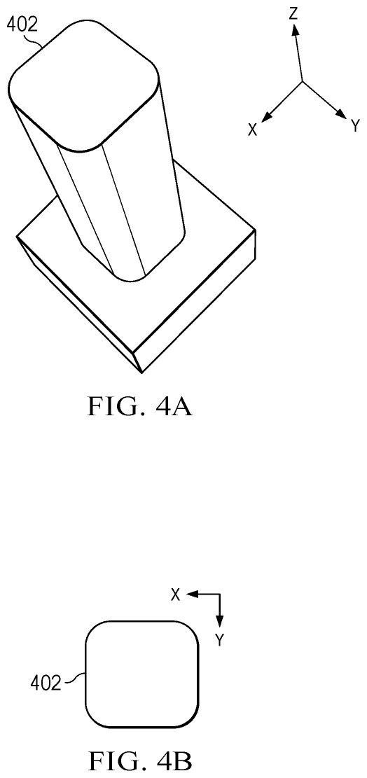

Referring back to FIG. 1, at block 104, a mask design for a photolithography process is generated based on area deviations of to-be-fabricated meta-atoms of a metalens and the target design of the metalens. Various examples compensate for fabrication or processing variation when generating a mask design. For example, photolithography processing, as described above, may result in rounding of corners of an exposed photoresist, and hence, in rounding of corners of a material (e.g., meta-atoms) that is etched to have the pattern of the photoresist transferred to that material. FIGS. 3A, 3B, 4A, and 4B illustrate corner rounding that may occur. FIGS. 3A and 3B are a perspective view and layout view, respectively, of a target design meta-atom 302. The target design meta-atom 302, in the layout view (e.g., an X-Y plane), has a rectangular area with sharp, 90 degree corners in this example. FIGS. 4A and 4B are a perspective view and layout view, respectively, of a fabricated meta-atom 402. The fabricated meta-atom 402 is generally rectangular but has rounding at corners. This rounding of corners may result from the photolithography process implemented to etch and pattern the material that resulted in the fabricated meta-atom 402. As described in detail subsequently, the generation of the mask design may reduce the area deviation between a target design meta-atom and the to-be-fabricated meta-atom that is to be fabricated (e.g., etched) using a photolithography process that implements a photolithography mask fabricated based on the mask design. In some examples, the generation of the mask design attempts to cause the area deviation between the target design meta-atom and the to-be-fabricated meta-atom to be zero (e.g., the area of the target design meta-atom is equal to the to-be-fabricated meta-atom).

Referring back to FIG. 1, at block 106, a photolithography mask 210 is fabricated based on the mask design. The photolithography mask 210 may be fabricated using any acceptable processing. At block 108, a metalens 232 is fabricated, and the fabrication of the metalens 232 includes using the photolithography mask 210 in a photolithography process. For example, the photolithography mask 210 may be used in a photolithography process to pattern a photoresist 212, and the patterned photoresist 212 is used as a mask for etching meta-atom material 214 into fabricated meta-atoms 234 of the metalens 232.

More specifically, the photolithography process may include generating light 220 from a light source 218, and transmitting the light 220 through the photolithography mask 210 to generate a pattern of light. The pattern of light is incident upon the photoresist 212 to pattern the photoresist 212. The pattern of the photoresist 212 is then transferred to the meta-atom material 214 using the photoresist 212 as a mask during an etch process to thereby form the fabricated meta-atoms 234. The metalens 232 may further include a substrate 216 upon which the meta-atom material 214, and hence, the fabricated meta-atoms 234, are disposed. The inset 232a of the metalens 232 shows a portion of the metalens 232, which includes a pattern of fabricated meta-atoms 234 that correspond to the target design meta-atoms 204 in the inset 202a of the target design 202.

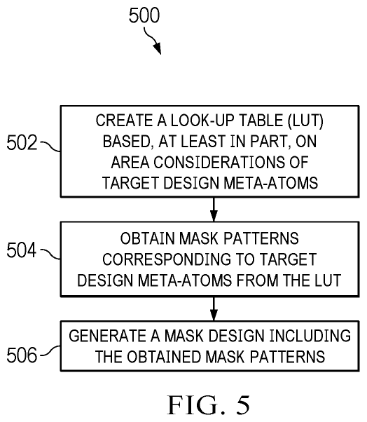

FIG. 5 is a first method 500 for generating a mask design in block 104 of FIG. 1 according to some examples. The first method 500 may be a rule-based correction to generate the mask design. At block 502, a Look-Up Table (LUT) is created based, at least in part, on area considerations of target design meta-atoms. The LUT is populated by various patterns of target design meta-atoms that may be implemented in a target design of a metalens. The LUT is indexed by the areas of target design meta-atoms, and may further be indexed by X-dimensions, Y-dimensions, and shapes of the target design meta-atoms. Further, the LUT may be indexed by dimensions of neighboring meta-atoms. Mask dimensions are a function of the target dimensions and may also be a function of neighboring patterns. For each indexed target design meta-atom of the LUT, the LUT contains a corresponding mask pattern for a photolithography mask that results in a given to-be-fabricated meta-atom. For an indexed target design meta-atom, the corresponding to-be-fabricated meta-atom has a reduced area deviation relative to the indexed target design meta-atom, which may be an area deviation of zero. The mask pattern for a given target design meta-atom may be determined through physical experimentation and/or photolithography simulation, and the mask pattern that is used to populate the LUT for a given target design meta-atom is the mask pattern that is determined to appropriately reduce the area deviation between the given target design meta-atom and the to-be-fabricated meta-atom.

At block 504, mask patterns corresponding to target design meta-atoms are obtained from the LUT. For example, for a given target design meta-atom, an area, and if applicable, dimensions, of the target design meta-atom, and if also applicable, dimensions of neighboring meta-atoms, are used to look up (e.g., by the indexing) a corresponding mask pattern. At block 506, a mask design that includes the obtained mask patterns is generated. The mask patterns can be placed in the mask design at locations that correspond to the respective target design meta-atoms in the target design.

With the mask design, the photolithography mask may be fabricated and implemented in a photolithography process to form fabricated meta-atoms, as described with respect to blocks 106, 108 of FIG. 1. Since the mask design was generated including mask patterns selected from the LUT, which is populated with mask patterns to reduce area deviation, the area deviation of the fabricated meta-atoms in the fabricated metalens relative to the target design meta-atoms of the target design may be reduced. The reduced area deviation may result in reduced optical efficiency loss of the fabricated metalens.

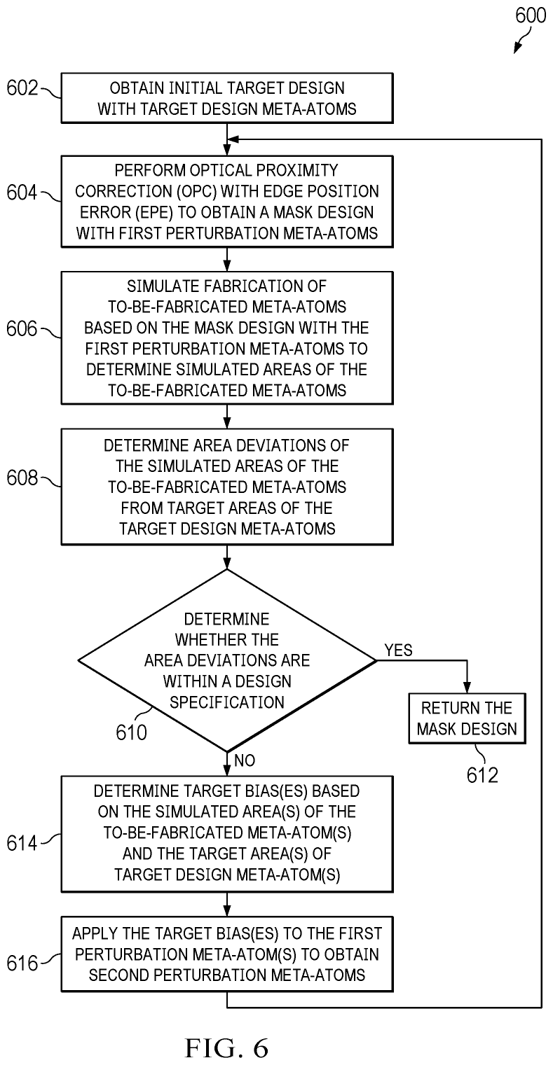

FIG. 6 is a second method 600 for generating a mask design in block 104 of FIG. 1 according to some examples. The second method 600 may be a model-based Optical Proximity Correction (OPC) with retargeting to generate the mask design. At block 602, an initial target design with target design meta-atoms is obtained, such as in block 102 of FIG. 1. At block 604, OPC with Edge Position Error (EPE) is performed to obtain a mask design with first perturbation meta-atoms. The OPC with EPE may, in an initial iteration, perturb (e.g., move) edges of various target design meta-atoms to obtain the mask design with first perturbation meta-atoms. In subsequent iterations, the OPC with EPE may further perturb edges of second perturbation meta-atoms (described subsequently) to obtain the mask design with first perturbation meta-atoms. For convenience herein, an area of a first perturbation meta-atom at iteration N is designated A_{PERTURB,N}(σB_{N-1}), where at N=1, B₀=0. Further, for convenience herein, a target bias determined at iteration N is designated B_{N}, and a damping factor is designated σ. The target bias and dampening factor are described subsequently. For clarity, the target bias entering an initial iteration N=1 is initialized to zero (e.g., B₀=0). Block 604 may implement any OPC with EPE technique.

At block 606, fabrication of to-be-fabricated meta-atoms is simulated based on the mask design with the first perturbation meta-atoms to determine simulated areas of the to-be-fabricated meta-atoms. The simulation may implement any lithography process simulation software, for example. The simulation can simulate the photolithography process using a simulated photolithography mask fabricated according to the mask design with the first perturbation meta-atoms, where the photolithography process is used to form (e.g., to pattern a photoresist for a mask to etch) the simulated to-be-fabricated meta-atoms. With the results of the simulation, simulated areas of the to-be-fabricated meta-atoms may be determined. For convenience herein, a simulated area of a to-be-fabricated meta-atom at iteration N is designated A_{2BFAB,N}(A_{PERTURB,N}(σB_{N-1}) or simply, A_{2BFAB,N}.

At block 608, area deviations of the simulated areas of the to-be-fabricated meta-atoms from target areas of the target design meta-atoms are determined. An area deviation is the difference between a simulated to-be-fabricated meta-atom and a target area of a corresponding target design meta-atom. As indicated previously, the simulated area is generated by simulating fabrication of a to-be-fabricated meta-atom, which fabrication is based on a corresponding first perturbation meta-atom in the mask design. An area of the first perturbation meta-atom is a function of any perturbation of edges in block 604 and any application of a target bias (described subsequently) in a previous iteration, if any. For convenience herein, a target area of a target design meta-atom is designated A_{TARGET}. Accordingly, an area deviation ΔA_{N} for a given to-be-fabricated meta-atom and corresponding target design meta-atom in an N iteration may be generalized as follows in Equation (1).

$$Δ {A}_{N} = {A}_{TARGET} - {A}_{2 BFAB , N} ( {A}_{PERTURB , N} ( σ {B}_{N - 1} ) ) \qquad Eq . ( 1 )$$

An area deviation may be determined for each to-be-fabricated meta-atom of the mask design and corresponding target design meta-atom at block 608.

At block 610, a determination is made whether the area deviations are within a design specification. For example, the design specification may be that no area deviation is greater than 10% of the area of a corresponding target design meta-atom. The design specification may be further tightened to, e.g., 2%, which may account for process drift during manufacturing. If the determination at block 610 is that the area deviations are within a design specification, the mask design is returned, at block 612, as the mask design to be fabricated (e.g., in block 106 of FIG. 1).

If the determination at block 610 is that the area deviations (e.g., any one or more area deviation) are not within a design specification, target bias(es) are determined, at block 612, based on the area(s) of simulated to-be-fabricated meta-atom(s) and the area(s) of target design meta-atom(s). A target bias is an amount by which a dimension of a first perturbation meta-atom is to be further perturbed, which results in modifying the area of the first perturbation meta-atom. Generally, a target bias is determined that may reduce the area deviation in a subsequent iteration. At the current iteration N, the area deviation in a subsequent iteration (N+1) may be an approximation, which is designated ΔÃ_{N+1} for convenience. For example, a difference between the target area of the target design meta-atom and an approximation of the simulated area of a to-be-fabricated meta-atom in the next iteration may be reduced, such as to approximately zero. The approximation of the simulated area of a to-be-fabricated meta-atom in the next iteration may be based on an incremental target bias, herein designated for convenience as δB_{N} at iteration N. For convenience herein, the approximation of the simulated area of a to-be-fabricated meta-atom in the next iteration (N+1) is designated Ã_{2BFAB,N+1}(A_{PERTURB,N+1}(σB_{N-1}+δB_{N})). Hence, the incremental target bias may be determined by generally solving Equation (2).

$$0 \approx Δ {\tilde{A}}_{N + 1} = {A}_{TARGET} - {\tilde{A}}_{2 BFAB , N + 1} ( {A}_{PERTURB , N + 1} ( σ {B}_{N - 1} + δ {B}_{N} ) ) \qquad Eq . ( 2 )$$

The target bias By at iteration N may accumulate or otherwise account for the target bias B_{N-1} from the previous iteration N−1 and the incremental target bias δB_{N} at iteration N (e.g., B_{N}=B_{N-1}+δB_{N}). Determining a target bias (and subsequently applying the target bias) may generally maintain the general shape of the area of the target design meta-atom to the area of a second perturbation meta-atom (e.g., maintain shape fidelity).

The target bias B_{N} may be or include a set of any number of target biases along respective axes. For example, for a target design area that is a square, the target bias B_{N} may be equal in both x and y-directions such that B_{N}=B_{x,N}=B_{y,N}. In other examples, for a non-square rectangular area, the target bias B_{N} may be a set that includes a target bias in an x-direction and another target bias in a y-direction such that B_{N}={B_{x,N}, B_{y,N}} where B_{x,N}≠B_{y,N}. Other shapes of a target design area may have different sets of a target bias. For example, a free-form shape may have a large number of target biases along any given axis. Equation (2) above may be solved analytically in some examples and may be solved numerically in other examples (such as for a free-form shape).

At block 616, the target bias(es) is applied to the first perturbation meta-atom(s) to obtain second perturbation meta-atoms. For example, one or more dimensions of a perturbation meta-atom may be modified based on the corresponding target bias, such as by adding or subtracting the target bias to the dimension(s). A target bias may be applied (e.g., added or subtracted) symmetrically around a center of the respective perturbation meta-atom. A damping factor σ may be applied to the target bias to improve convergence of correction iterations by reducing oscillating over-correction. The damping factor may be, for example, between 0.7 and 0.9 in an initial iteration(s) and may be reduced, such as to approximately 0.5, in subsequent iterations. For convenience herein, an area of a second perturbation meta-atom in which the target bias is applied at iteration N is designated A_{PERTURB,N}(σB_{N}).

Then, at block 604, in a subsequent iteration, the OPC with EPE is performed on the second perturbation meta-atoms with the target bias(es) to obtain a mask design with first perturbation meta-atoms. The loop of blocks 604, 606, 608, 610, 614, 616 may be performed any number of iterations, such as until the area deviations are within the design specification as determined by block 610. A loop counter and condition to exit the loop based on the loop counter or another condition may be implemented, e.g., to avoid infinite looping.

With the mask design, the photolithography mask may be fabricated and implemented in a photolithography process to form fabricated meta-atoms, as described with respect to blocks 106, 108 of FIG. 1. Since the mask design was generated based on biasing the target design meta-atoms, the area deviation of the fabricated meta-atoms in the fabricated metalens relative to the target design meta-atoms of the target design may be reduced. The reduced area deviation may result in reduced optical efficiency loss of the fabricated metalens.

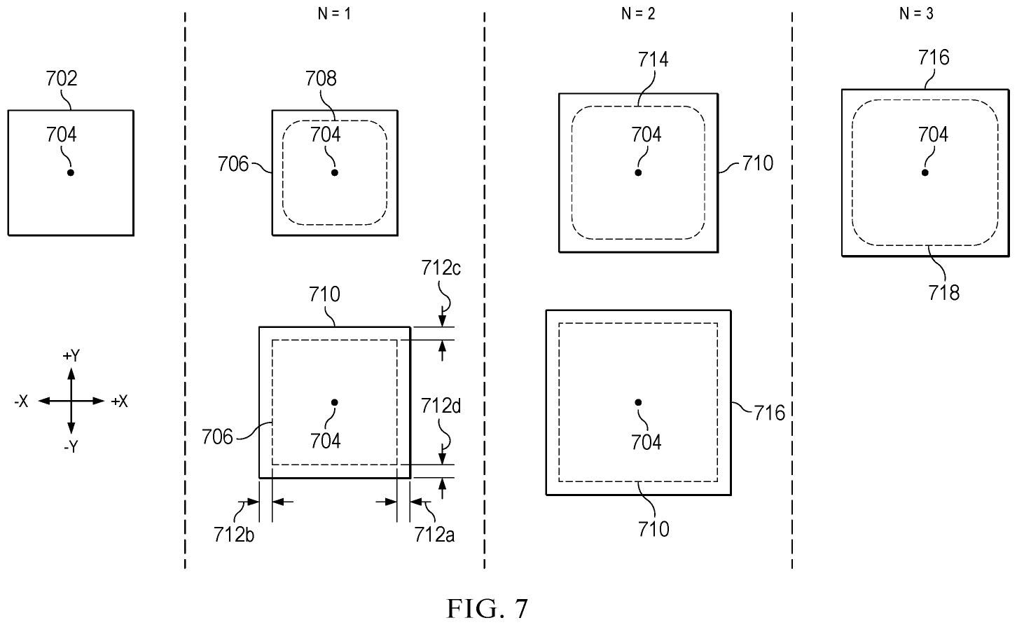

A simple example of some operations of the second method 600 of FIG. 6 is described in the context of FIG. 7. In this example, the shape of the area of the target design meta-atom is a square. For simplicity, it is assumed that no perturbation occurs in block 604. That is, in an initial iteration N=1, for a given target design meta-atom, an area of the first perturbation meta-atom is equal to an area of the target design meta-atom (as shown in Equation (3)), and for subsequent iterations N>1, an area of the first perturbation meta-atom is equal to an area of the second perturbation meta-atom with the target bias applied in the previous iteration (N−1) (as shown in Equation (4). Generally, these assumptions result in the following:

$${A}_{PERTURB , 1} ( σ {B}_{0} = 0 ) = {A}_{TARGET} for N = 1 \qquad Eq . ( 3 )$$

$${A}_{PERTURB , N} ( σ {B}_{N - 1} ) = {A}_{PERTURB , N - 1} ( σ {B}_{N - 1} ) = {( \sqrt{{A}_{TARGET}} + σ {B}_{N - 1} )}^{2} for N > 1 \qquad Eq . ( 4 )$$

Further, as a result of the shape of the area of the target design meta-atom being a square, an incremental area change of the first perturbation meta-atom as a result of the incremental target bias at iteration N may be generalized as shown in Equation (5).

$$δ {A}_{PERTURB , N} ( δ {B}_{N} ) = ( δ {B}_{N} ) ( ( δ {B}_{N} ) + 2 σ {B}_{N - 1} + 2 \sqrt{{A}_{TARGET}} ) \qquad Eq . ( 5 )$$

FIG. 7 shows an area 702 of the target design meta-atom (e.g., A_{TARGET}) with a center 704. The shape of the area 702 is a square in this example. In a first iteration N=1, based on the assumptions of Equation (3) above, an area 706 of a first perturbation meta-atom (following block 606) is equal to the area 702 of the target design meta-atom. The simulation based on the area 706 of the first perturbation meta-atom results in a simulated area 708 of a to-be-fabricated meta-atom (e.g., A_{2BFAB,1}(A_{PERTURB,1}(σB₀=0))). It is assumed that area deviation ΔA₁ exceeds a design specification.

To solve for the target bias, it is assumed that the area of the to-be-fabricated meta-atom is approximately the area of the first perturbation meta-atom of the next iteration. Hence, for iteration N=1, the approximation of the area of the to-be-fabricated meta-atom of the next iteration N=2 is equal to the area of the first perturbation meta-atom of the next iteration N=2 perturbed by an incremental target bias (e.g., Ã_{2BFAB,2} (A_{PERTURB,2}(δB₁)=A_{PERTURB,2}(δB₁)). The area of the first perturbation meta-atom of the next iteration N=2 is approximated to be the simulated area of the to-be-fabricated meta-atom of the current iteration N=1 plus the incremental area change of the first perturbation meta-atom by applying the incremental target bias (e.g., A_{PERTURB,2}(δB₁)=A_{2BFAB,1}+δA_{PERTURB,1}(δB₁)). Substituting these approximations into Equation (2) above results in Equation (6) below.

$$0 = {A}_{TARGET} - ( {A}_{2 BFAB , 1} + δ {A}_{PERTURB , 1} ( δ {B}_{1} ) ) \qquad Eq . ( 6 )$$

Substituting into Equation (5) into Equation (6), where B₀=0, results in Equation (7).

$$0 = {A}_{TARGET} - {A}_{2 BFAB , 1} - {( δ {B}_{1} )}^{2} - 2 ( δ {B}_{1} ) \sqrt{{A}_{TARGET}} \qquad Eq . ( 7 )$$

Rearranging terms of Equation (7) yields Equations (8) and (9) below.

$$0 = {( \sqrt{{A}_{TARGET}} - ( δ {B}_{1} ) )}^{2} - {( \sqrt{{A}_{2 BFAB , 1}} )}^{2} \qquad Eq . ( 8 )$$

$$0 = ( \sqrt{{A}_{TARGET}} - ( δ {B}_{1} ) + \sqrt{{A}_{2 BFAB , 1}} ) ( \sqrt{{A}_{TARGET}} - ( δ {B}_{1} ) - \sqrt{{A}_{2 BFAB , 1}} ) \qquad Eq . ( 9 )$$

Solving Equation (9) for the incremental target bias renders Equation (10) below.

$$δ {B}_{1} = \sqrt{{A}_{TARGET}} - \sqrt{{A}_{2 BFAB , 1}} \qquad Eq . ( 10 )$$

Because there has been no previous iteration target bias, the target bias for iteration N=1 is equal to the incremental target bias (e.g., B₁=δB₁).

The target bias is applied with a damping factor to the first perturbation meta-atom to obtain a second perturbation meta-atom of the iteration N=1 (e.g., A_{PERTURB,1}(δB₁)). The application of the target bias and damping factor results in an area 710 of a second perturbation meta-atom. The dampened target bias is applied symmetrically around the center 704 along a given axis. Hence, half 712a of the dampened target bias (e.g., σB₁/2) is added to the length in a +x direction, and another half 712b is added to the length in a −x direction. Similarly, half 712c of the dampened target bias is added to the length in a +y direction, and another half 712d is added to the length in a −y direction.

In a second iteration N=2, based on the assumption of Equation (4) above, an area 710 of a first perturbation meta-atom (following block 606) is equal to the area 710 of the second perturbation meta-atom with the target bias applied in the previous iteration N=1 (e.g., A_{PERTURB,2}(σB₁)=A_{PERTURB,1}(σB₁)). The simulation based on the area 710 of the first perturbation meta-atom results in a simulated area 714 of a to-be-fabricated meta-atom (e.g., A_{2BFAB,2}((σB₁))). It is assumed that area deviation ΔA₂ exceeds a design specification.

To solve for the target bias, it is assumed that the area of the to-be-fabricated meta-atom is approximately the area of the first perturbation meta-atom of the next iteration. Hence, for iteration N=2, the approximation of the area of the to-be-fabricated meta-atom of the next iteration N=3 is equal to the area of the first perturbation meta-atom of the next iteration N=3 perturbed by an incremental target bias (e.g., Ã_{2BFAB,3}(A_{PERTURB,3}(σB₁+δB₂))=A_{PERTURB,3}(σB₁+δB₂)). The area of the first perturbation meta-atom of the next iteration N=3 is approximated to be the simulated area of the to-be-fabricated meta-atom of the current iteration N=2 plus the incremental area change of the first perturbation meta-atom by applying the incremental target bias (e.g., A_{PERTURB,3}(σB₁+δB₂)=A_{2BFAB,2}+δA_{PERTURB,2}(δB₂)). Substituting these approximations into Equation (2) above results in Equation (11) below.

$$0 = {A}_{TARGET} - ( {A}_{2 BFAB , 2} + δ {A}_{PERTURB , 2} ( δ {B}_{2} ) ) \qquad Eq . ( 11 )$$

Substituting into Equation (5) into Equation (11) results in Equation (12).

$$0 = {A}_{TARGET} - {A}_{2 BFAB , 1} - ( δ {B}_{2} ) ( ( δ {B}_{2} ) + 2 σ {B}_{1} + 2 \sqrt{{A}_{TARGET}} ) \qquad Eq . ( 12 )$$

Rearranging terms from Equation (12) yields Equation (13), from which the quadratic formula is used to solve for the incremental target bias in Equation (14) below.

$$0 = {( δ {B}_{2} )}^{2} + 2 ( σ {B}_{1} + \sqrt{{A}_{TARGET}} ) ( δ {B}_{2} ) + ( {A}_{2 BFAB , 1} - {A}_{TARGET} ) \qquad Eq . ( 13 )$$

$$δ {B}_{2} = \frac{\begin{matrix}- 2 ( σ {B}_{1} + \sqrt{{A}_{TARGET}} ) \pm \\ \sqrt{( {( 2 ( σ {B}_{1} + \sqrt{{A}_{TARGET}} ) )}^{2} - 4 ( {A}_{2 BFAB , 1} - {A}_{TARGET} ) )}\end{matrix}}{2} \qquad Eq . ( 14 )$$

The iteration target bias from the previous iteration N=1 is added to the incremental target bias to obtain the target bias for iteration N=2 (e.g., B₂=B₁+δB₂).

The target bias is applied with a damping factor to the first perturbation meta-atom to obtain the second perturbation meta-atom (e.g., A_{PERTURB,2}(σB₂)). The application of the target bias and damping factor results in an area 716 of a second perturbation meta-atom. The dampened target bias is applied symmetrically around the center 704 along a given axis, like described previously.

In a third iteration N=3, based on the assumption of Equation (4) above, an area 716 of a first perturbation meta-atom (following block 606) is equal to the area 716 of the second perturbation meta-atom with the target bias applied in the previous iteration N=2 (e.g., A_{PERTURB,3}(σB₂)=A_{PERTURB,2}(σB₂)). The simulation based on the area 716 of the first perturbation meta-atom results in a simulated area 718 of a to-be-fabricated meta-atom (e.g., A_{2BFAB,3}(A_{PERTURB,3}(σB₂))). It is assumed that area deviation ΔA₃ is within a design specification. Hence, the area 716 of the first perturbation meta-atom is returned to generate a design mask.

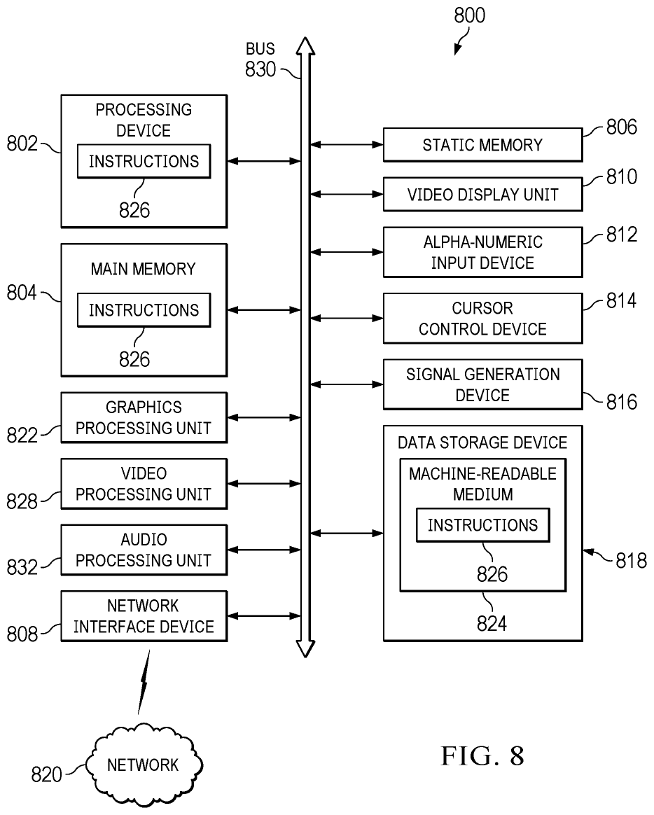

FIG. 8 illustrates an example machine of a computer system 800 within which a set of instructions, for causing the machine to perform any one or more of the methodologies discussed herein, may be executed. More particularly, the computer system 800 may include stored instruction (e.g., stored on a non-transitory computer-readable medium) that, when executed by one or more processors of the computer system 800, implement the methodologies, in whole or in part, of blocks 102, 104, and/or methods 500, 600 of FIGS. 1, 5 and 6. In various examples, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM)), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable storage medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a non-transitory computer-readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable storage medium having stored thereon instructions, which may be used to program a computer system (or other electronic devices) to perform a process according to the present disclosure. A machine-readable storage medium includes any mechanism for storing information in a form readable by a machine (e.g., a computer). For example, a machine-readable (e.g., a computer-readable) storage medium includes a machine-readable (e.g., a computer-readable) storage medium such as a read only memory (ROM), random access memory (RAM), magnetic disk storage media, optical storage media, flash memory devices, etc.

An example is a method. A target design of a metalens is obtained. The target design includes target design meta-atoms. A mask design is generated, by one or more processors, based on area deviations of to-be-fabricated meta-atoms of the metalens relative to the target design meta-atoms.

Another example is a non-transitory computer-readable storage medium comprising stored instructions. The instructions, which when executed by one or more processors, cause the one or more processors to obtain a target design of a metalens and generate a mask design based on area deviations. The target design includes target design meta-atoms. The area deviations are of to-be-fabricated meta-atoms of the metalens relative to the target design meta-atoms.

A further example is a method. A target design of a metalens is obtained. The target design includes target design meta-atoms. The target design meta-atoms have corresponding first to-be-fabricated meta-atoms. A mask design is generated by one or more processors. The mask design includes modified meta-atoms corresponding to the target design meta-atoms. The modified meta-atoms have corresponding second to-be-fabricated meta-atoms. For each modified meta-atom of the modified meta-atoms, an area deviation between an area of the corresponding target design meta-atom and an area of the corresponding second to-be-fabricated meta-atom is less than an area deviation between the area of the corresponding target design meta-atom and an area of the corresponding first to-be-fabricated meta-atom.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
obtaining a target design of a metalens, the target design including target design meta-atoms; and
generating, by one or more processors, a mask design based on area deviations of to-be-fabricated meta-atoms of the metalens relative to the target design meta-atoms.

2. The method of claim 1 further comprising:
fabricating a photolithography mask based on the mask design; and
fabricating the metalens comprising using the photolithography mask in a photolithography process.

3. The method of claim 1, wherein generating the mask design comprises:
obtaining a look-up table comprising mask patterns, each mask pattern of the mask patterns being indexed in the look-up table by, at least in part, an area of a corresponding target design meta-atom;
for each target design meta-atom of the target design meta-atoms, obtaining a mask pattern from the look-up table corresponding to an area of the respective target design meta-atom; and
generating the mask design comprising the obtained mask patterns.

4. The method of claim 1, wherein generating the mask design comprises:
performing an optical proximity correction with edge position error technique based on the target design to obtain a provisional mask design including first perturbation meta-atoms;
simulating to-be-fabricated meta-atoms based on the provisional mask design;
determining area deviations of the simulated to-be-fabricated meta-atoms from the target design meta-atoms;
when the area deviations are within a design specification, assigning the provisional mask design as the mask design; and
when the area deviations are not within the design specification:
determining, for each area deviation of the area deviations not within the design specification, a target bias based on an area of a corresponding simulated to-be-fabricated meta-atom and an area of a corresponding target design meta-atom; and
applying, for each determined target bias, the respective target bias to the corresponding first perturbation meta-atom in the provisional mask design to obtain a corresponding second perturbation meta-atom in the provisional mask design.

5. The method of claim 4, wherein the target bias is determined based on a difference between the area of the corresponding target design meta-atom and an approximation of an area of a to-be-simulated to-be-fabricated meta-atom, the area of the to-be-simulated to-be-fabricated meta-atom being based on the corresponding simulated to-be-fabricated meta-atom and an incremental area change of the corresponding first perturbation meta-atom based on an incremental target bias.

6. The method of claim 4, wherein applying the respective target bias further includes applying a damping factor with the respective target bias to the corresponding first perturbation meta-atom in the provisional mask design to obtain the corresponding second perturbation meta-atom in the provisional mask design.

7. The method of claim 1, wherein generating the mask design comprises:
iteratively until area deviations are within a design specification:
performing an optical proximity correction with edge position error technique based on a design to obtain a provisional mask design including first perturbation meta-atoms, the design being the target design in an initial iteration and being the provisional mask design from a preceding iteration in a subsequent iteration;
simulating to-be-fabricated meta-atoms based on the provisional mask design;
determining the area deviations of the simulated to-be-fabricated meta-atoms from the target design meta-atoms;
determining, for each area deviation of the area deviations not within the design specification, a target bias based on an area of a corresponding simulated to-be-fabricated meta-atom and an area of a corresponding target design meta-atom; and
applying, for each determined target bias, the respective target bias to the corresponding first perturbation meta-atom in the provisional mask design to obtain a corresponding second perturbation meta-atom in the provisional mask design; and
assigning the provisional mask design as the mask design.

8. The method of claim 7, wherein the target bias is determined based on a difference between the area of the corresponding target design meta-atom and an approximation of an area of a to-be-simulated to-be-fabricated meta-atom, the area of the to-be-simulated to-be-fabricated meta-atom being based on the corresponding simulated to-be-fabricated meta-atom and an incremental area change of a corresponding first perturbation meta-atom based on an incremental target bias.

9. The method of claim 7, wherein applying the respective target bias further includes applying a damping factor with the respective target bias to the corresponding first perturbation meta-atom in the provisional mask design to obtain the corresponding second perturbation meta-atom in the provisional mask design.

10. A non-transitory computer-readable storage medium comprising stored instructions, which when executed by one or more processors, cause the one or more processors to:
obtain a target design of a metalens, the target design including target design meta-atoms; and
generate a mask design based on area deviations of to-be-fabricated meta-atoms of the metalens relative to the target design meta-atoms.

11. The non-transitory computer-readable storage medium of claim 10, wherein the instructions, which when executed by the one or more processors, cause the one or more processors to generate the mask design further includes instructions, which when executed by the one or more processors, cause the one or more processors to:
obtain a look-up table comprising mask patterns, each mask pattern of the mask patterns being indexed in the look-up table by, at least in part, an area of a corresponding target design meta-atom;
for each target design meta-atom of the target design meta-atoms, obtain a mask pattern from the look-up table corresponding to an area of the respective target design meta-atom; and
generate the mask design comprising the obtained mask patterns.

12. The non-transitory computer-readable storage medium of claim 10, wherein the instructions, which when executed by the one or more processors, cause the one or more processors to generate the mask design further includes instructions, which when executed by the one or more processors, cause the one or more processors to:
perform an optical proximity correction with edge position error technique based on the target design to obtain a provisional mask design including first perturbation meta-atoms;
simulate to-be-fabricated meta-atoms based on the provisional mask design;
determine area deviations of the simulated to-be-fabricated meta-atoms from the target design meta-atoms;
when the area deviations are within a design specification, assign the provisional mask design as the mask design; and
when the area deviations are not within the design specification:
determine, for each area deviation of the area deviations not within the design specification, a target bias based on an area of a corresponding simulated to-be-fabricated meta-atom and an area of a corresponding target design meta-atom; and
apply, for each determined target bias, the respective target bias to the corresponding first perturbation meta-atom in the provisional mask design to obtain a corresponding second perturbation meta-atom in the provisional mask design.

13. The non-transitory computer-readable storage medium of claim 12, wherein the target bias is determined based on a difference between the area of the corresponding target design meta-atom and an approximation of an area of a to-be-simulated to-be-fabricated meta-atom, the area of the to-be-simulated to-be-fabricated meta-atom being based on the corresponding simulated to-be-fabricated meta-atom and an incremental area change of the corresponding first perturbation meta-atom based on an incremental target bias.

14. The non-transitory computer-readable storage medium of claim 10, wherein the instructions, which when executed by the one or more processors, cause the one or more processors to generate the mask design further includes instructions, which when executed by the one or more processors, cause the one or more processors to:
iteratively until area deviations are within a design specification:
perform an optical proximity correction with edge position error technique based on a design to obtain a provisional mask design including first perturbation meta-atoms, the design being the target design in an initial iteration and being the provisional mask design from a preceding iteration in a subsequent iteration;
simulate to-be-fabricated meta-atoms based on the provisional mask design;
determine the area deviations of the simulated to-be-fabricated meta-atoms from the target design meta-atoms;
determine, for each area deviation of the area deviations not within the design specification, a target bias based on an area of a corresponding simulated to-be-fabricated meta-atom and an area of a corresponding target design meta-atom; and
apply, for each determined target bias, the respective target bias to the corresponding first perturbation meta-atom in the provisional mask design to obtain a corresponding second perturbation meta-atom in the provisional mask design; and
assign the provisional mask design as the mask design.

15. The non-transitory computer-readable storage medium of claim 14, wherein the target bias is determined based on a difference between the area of the corresponding target design meta-atom and an approximation of an area of a to-be-simulated to-be-fabricated meta-atom, the area of the to-be-simulated to-be-fabricated meta-atom being based on the corresponding simulated to-be-fabricated meta-atom and an incremental area change of a corresponding first perturbation meta-atom based on an incremental target bias.

16. A method comprising:
obtaining a target design of a metalens, the target design including target design meta-atoms, the target design meta-atoms having corresponding first to-be-fabricated meta-atoms; and
generating, by one or more processors, a mask design including modified meta-atoms corresponding to the target design meta-atoms, the modified meta-atoms having corresponding second to-be-fabricated meta-atoms, wherein for each modified meta-atom of the modified meta-atoms, an area deviation between an area of the corresponding target design meta-atom and an area of the corresponding second to-be-fabricated meta-atom is less than an area deviation between the area of the corresponding target design meta-atom and an area of the corresponding first to-be-fabricated meta-atom.

17. The method of claim 16, wherein generating the mask design is rule-based based on areas of the target design meta-atoms.

18. The method of claim 16, wherein generating the mask design uses a look-up table (LUT) including available modified meta-atoms indexed based on respective areas of target design meta-atoms.

19. The method of claim 16, wherein generating the mask design is model-based based on area deviations of respective areas of target design meta-atoms and respective approximations of areas of simulated to-be-fabricated meta-atoms.

20. The method of claim 16, wherein generating the mask design includes, for each modified meta-atom of the modified meta-atoms:
determining a target bias based on an area of the corresponding target design meta-atom and an approximation of an area of a to-be-fabricated meta-atom resulting from the respective modified meta-atom; and
applying the target bias to the area of the corresponding target design meta-atom, wherein the target bias applied to the area of the corresponding target design meta-atom at least in part obtains the respective modified meta-atom.
